(19) United States
(12) Patent Application Publication
(10) Pub. No.: US 2013/0249044 A1
(43) Pub. Date: Sep. 26, 2013

(54) SEMICONDUCTOR DEVICE

(71) Applicant: KABUSHIKI KAISHA TOSHIBA, Tokyo (JP)

(72) Inventors: Satoshi HARUKI, Kanagawa (JP); Kazuhiro Kato, Kanagawa (JP)

(73) Assignee: Kabushiki Kaisha Toshiba, Tokyo (JP)

(21) Appl. No.: 13/779,545

(22) Filed: Feb. 27, 2013

(30) Foreign Application Priority Data
Mar. 23, 2012 (JP) 2012-066890

(51) Int. Cl. H01L 27/02

(52) U.S. Cl. CPC H01L 27/0248
USPC 257/491

(57) ABSTRACT

A semiconductor device includes a first diode, a second diode, and a third diode. The first diode has an anode connected to a first power supply terminal to which a first power-source voltage is applied and a cathode connected to an input-output terminal at which input-output signals are input and output. The second diode has an anode connected to the input-output terminal and a cathode connected to a second power supply terminal to which a second power-source voltage that is higher than the first power-source voltage is applied. The third diode has an anode connected to the first supply terminal and a cathode connected to the second power supply terminal. The breakdown voltage of at least one of either the first or second diode is higher than the breakdown voltage of the third diode.

### CROSS-REFERENCE TO RELATED APPLICATION

This application is based upon and claims the benefit of priority from Japanese Patent Application No. 2012-066890, filed Mar. 23, 2012; the entire contents of which are incorporated herein by reference.

### FIELD

Embodiments described herein relate a semiconductor device.

### BACKGROUND

Traditionally, to protect internal circuits from a surge, a protection circuit is placed between the power supply terminal and the input-output terminal as well as between the input-output terminal and a ground terminal. This protection circuit controls the flow of an electric current if a surge is applied to the power supply terminal, input-output terminal, or the ground terminal, and functions so that high voltage will not be impressed on the internal circuit. If a surge is applied, the diode used in the protection circuit must not break when the electric current flows in the forward or reverse direction. To withstand a current flow in the reverse direction, which is lower compared with the forward direction, it is necessary to make the size of the element larger and to secure protection by lowering the current density. For this reason, there is a tendency for the size of the integrated semiconductor circuit to increase. However, it is desirable to design this kind of protection circuit to have a small circuit area.

### DESCRIPTION OF THE DRAWINGS

FIG. 1 is a circuit diagram that shows a semiconductor device according to a first embodiment.

FIG. 2 is a circuit diagram that shows a semiconductor device according to a second embodiment.

FIG. 3 is a circuit diagram that shows a semiconductor device according to a third embodiment.

FIG. 4 is a circuit diagram that shows a semiconductor device according to a fourth embodiment.

FIG. 5 is a circuit diagram that shows a semiconductor device according to a fifth embodiment.

FIG. 6 is a circuit diagram that shows a semiconductor device according to a sixth embodiment.

### DETAILED DESCRIPTION

Embodiments provide a semiconductor device that includes a protection circuit configuration that can have a scaled-down circuit area.

A semiconductor device according to an embodiment includes a first diode, a second diode, and a third diode. The first diode has an anode connected to a first power supply terminal that is supplied with a first power-supply voltage and a cathode connected to an input-output terminal at which input-output signals are input and output. The second diode has an anode connected to the input-output terminal and a cathode connected to a second power supply terminal to which a second power-supply voltage that is higher than the first power-supply voltage is applied. The third diode has an anode connected to the first power supply terminal and a cathode connected to the second power supply terminal. The breakdown voltage of at least one of the first diode and the second diode is higher than the breakdown voltage of the third diode.

### First Embodiment

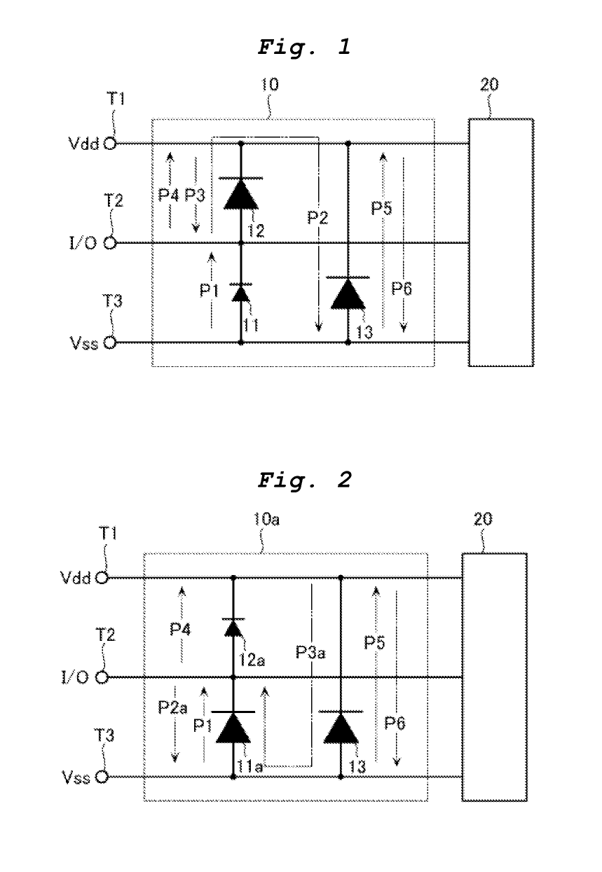

The composition of the semiconductor device according to the first embodiment will be described with reference to FIG. 1. The semiconductor device according to the first embodiment, as shown in FIG. 1, includes a protection circuit 10 and an internal circuit 20. The protection circuit 10 provides protection so that a surge is not applied to the internal circuit 20 if a surge is applied to the power supply terminal T1, the input-output terminal T2, or the ground terminal T3. The internal circuit 20 is supplied with a power-supply voltage Vdd from the power supply terminal T1, and is supplied with a ground voltage Vss (Vss<Vdd) from the ground terminal T3. Also, the internal circuit 20 is input with various signals from the input-output terminal T2, and outputs various signals to the input-output terminal T2.

The protection circuit 10, as shown in FIG. 1, includes diodes 11, 12, and 13. Diode 11 has an anode connected to the ground terminal T3 and a cathode connected to the input-output terminal T2. The diode 12 has an anode connected to the input-output terminal T2 and a cathode connected to the power supply terminal T1. The diode 13 has an anode connected to the ground terminal T3 and a cathode connected to the power supply terminal T1. The breakdown voltage of the diode 11 is higher than the breakdown voltage of the diodes 12 and 13. In contrast, the breakdown voltage of the diode 12 is nearly equal to the breakdown voltage of the diode 13. Due to the relationships among these breakdown voltages (which will be discussed later), a reverse current does not flow through the diode 11, and the element size (e.g., element area size) of the diode 11 can be made smaller than the element size of the diodes 12 and 13.

Next, the flow of the electric current in the first embodiment when a negative surge is applied to the input-output terminal T2 with the ground terminal T3 as the reference is described. In this case, as shown in path P1, a current in the forward direction flows through the diode 11. With this, the negative surge is discharged, and the protection circuit 10 protects the internal circuit 20.

Next, the flow of the electric current in the first embodiment when a positive surge is applied to the input-output terminal T2 with the ground terminal T3 as the reference is described. In this case, because the breakdown voltage of the diode 11 is higher than the breakdown voltage of the diode 13, a reverse current does not flow through the diode 11. Therefore, as shown in path P2, an electric current in the forward direction flows through the diode 12, and an electric current in the reverse direction flows through the diode 13. With this, the positive surge is discharged, and the protection circuit 10 protects the internal circuit 20.

Next, the flow of the electric current in the first embodiment when a negative charge is applied to the input-output terminal T2 with the power supply terminal T1 as the reference is described. In this case, as shown in path P3, an electrical current in the reverse direction flows through the diode 12. With this, the negative surge is discharged, and the protection circuit 10 protects the internal circuit 20.

Next, the flow of the electric current in the first embodiment when a positive surge is applied to the input-output terminal T2 with the power supply terminal T1 as the reference is described. In this case, as shown in path P4, an electric current in the forward direction flows through the diode 12. With this, the positive surge is discharged, and the protection circuit 10 protects the internal circuit 20.

Next, the flow of the electric current in the first embodiment when a negative surge is applied to the power supply terminal T1 with the ground terminal T3 as the reference is described. In this case, as shown in path P5, an electric current in the forward direction flows through the diode 13. With this, the negative surge is discharged, and the protection circuit 10 protects the internal circuit 20.

Next, the flow of the electric current in the first embodiment when a positive surge is applied to the power supply terminal T1 with the ground terminal T3 as the reference is described. In this case, as shown in path P6, an electric current in the reverse direction flows the diode 13. With this, the positive surge is discharged, and the protection circuit 10 protects the internal circuit 20.

Thus, the first embodiment can discharge surges that have patterns based on the relationships among the breakdown voltages. Furthermore, because a reverse current does not flow through the diode 11, the element size of the diode 11 can be made smaller than the element size of the diodes 12 and 13. That is, the first embodiment can protect the internal circuit 20 with a reduced circuit area.

### Second Embodiment

Next, the semiconductor device according to the second embodiment is described with reference to FIG. 2. FIG. 2 is a circuit diagram of the semiconductor device according to the second embodiment. The protection circuit 10a according to the second embodiment, as shown in FIG. 2, includes the diode 11a instead of the diode 11 and includes the diode 12a instead of the diode 12.

The diode 11a has an anode connected to the ground terminal T3 and a cathode connected to the input-output terminal T2. The diode 12a has an anode connected to the input-output terminal T2 and a cathode connected to the power supply terminal T1. In this point, the second embodiment is the same as the first embodiment. However, the breakdown voltage of the diode 11a is nearly equal to the breakdown voltage of the diode 13, and the breakdown voltage of the diode 12a is higher than the breakdown voltage of the diode 13. Due to the relationships among these breakdown voltages and because a reverse current does not flow through the diode 12a, the element size of the diode 12a can be made smaller than the element size of the diodes 11a and 13.

Next, the flow of the electric current in the second embodiment when a negative surge is applied to the input-output terminal T2 with the ground terminal T3 as reference is described. In this case, in the same way as the first embodiment and as shown in path P1, an electric current in the forward direction flows through the diode 11a. With this, the negative surge is discharged, and the protection circuit 10a protects the internal circuit 20.

Next, the flow of the electric current in the second embodiment when a positive surge is applied to the input-output terminal T2 with the ground terminal T3 as reference is described. In this case, as shown in path P2a, an electric current in the reverse direction flows through the diode 11a. With this, the positive surge is discharged, and the protection circuit 10a protects the internal circuit 20.

Next, the flow of the electric current in the second embodiment when a negative surge is applied to the input-output terminal T2 with the power supply terminal T1 as the reference is described. In this case, because the breakdown voltage of the diode 12a is higher than the breakdown voltage of the diode 13, a reverse current does not flow through the diode 12a. Therefore, as shown in path P3a, an electric current in the reverse direction flows through the diode 13, and a current in the forward direction flows through the diode 11a. With this, the negative surge is discharged, and the protection circuit 10a protects the internal circuit 20.

Next, the flow of the electric current in the second embodiment when a positive surge is applied to the input-output terminal T2 with the power supply terminal T1 as the reference is described. In this case, in the same way as the first embodiment and as shown in path P4, an electric current in the forward direction flows through the diode 12a. With this, the positive surge is discharged, and the protection circuit 10a protects the internal circuit 20.

Next, the flow of the electric current in the second embodiment when a negative surge is applied to the power supply terminal T1 with the ground terminal T3 as the reference is described. In this case, in the same way as the first embodiment and as shown in path P5, an electric current in the forward direction flows through the diode 13. With this, the negative surge is discharged, and the protection circuit 10a protects the internal circuit 20.

Next, the flow of the electric current in the second embodiment when a positive surge is applied to the power supply terminal T1 with the ground terminal T3 as the reference is described. In this case, in the same way as the first embodiment and as shown in path P6, an electric current in the reverse direction flows through the diode 13. With this, the positive surge is discharged, and the protection circuit 10a protects the internal circuit 20.

Thus, the second embodiment can discharge surges that have patterns based on the relationships among the breakdown voltages. Furthermore, the element size of the diode 12a can be made smaller than the element size of the diodes 11 and 13. That is, the second embodiment can protect the internal circuit 20 with a reduced circuit area.

### Third Embodiment

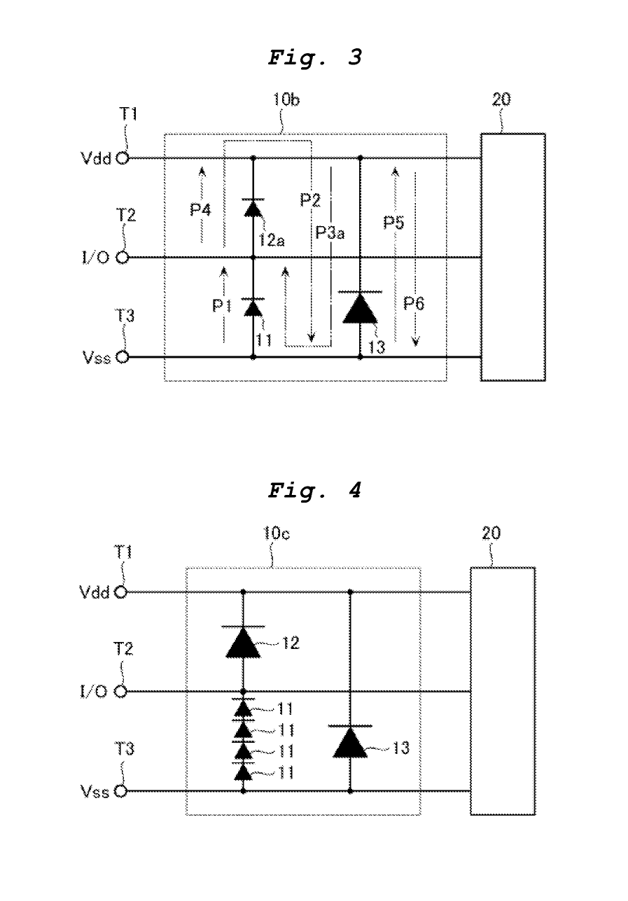

Next, the semiconductor device according to the third embodiment is described with reference to FIG. 3. FIG. 3 is a circuit diagram of the semiconductor device according to the third embodiment. The protection circuit 10b according to the third embodiment, as shown in FIG. 3, includes the diodes 11, 12a, and 13. The breakdown voltages of the diodes 11 and 12a are higher than the breakdown voltage of the diode 13. Therefore, the element sizes of the diodes 11 and 12a can be made smaller than the element size of the diode 13.

Next, the flow of the electric current in the third embodiment when a negative surge is applied to the input-output terminal T2 with the ground terminal T3 as the reference is described. In this case, in the same way as the first embodiment and as shown in path P1, an electric current in the forward direction flows through the diode 11. With this, the negative surge is discharged, and the protection circuit 10b protects the internal circuit 20.

Next, the flow of the electric current in the third embodiment when a positive surge is applied to the input-output terminal T2 with the ground terminal T3 as reference is described. In this case, because the breakdown voltage of the diode 11 is higher than the breakdown voltage of the diode 13, the diode 11 does not apply a reverse current. Therefore, in the same way as the first embodiment and as shown in path P2, an electric current in the forward direction flows through the diode 12a, and an electric current in the reverse direction flows through the diode 13. With this, the positive surge is discharged, and the protection circuit 10b protects the internal circuit 20.

Next, the flow of the electric current in the third embodiment when a negative surge is applied to the input-output terminal T2 with the power supply terminal T1 as the reference is described. In this case, because the breakdown voltage of the diode 12a is higher than the breakdown voltage of the diode 13, a reverse current does not flow through the diode 12a. Therefore, in the same way as the second embodiment and as shown in path P3a, an electric current in the reverse direction flows through the diode 13, and an electric current in the forward direction flows through the diode 11. With this, the negative surge is discharged, and the protection circuit 10b protects the internal circuit 20.

Next, the flow of the electric current in the third embodiment when a positive surge is applied to the input-output terminal T2 with the power supply terminal T1 as the reference is described. In this case, in the same way as the first embodiment and as shown in path P4, an electric current in the forward direction flows through the diode 12a. With this, the positive surge is discharged, and the protection circuit 10b protects the internal circuit 20.

Next, the flow of the electric current in the third embodiment when a negative surge is applied to the power supply terminal T1 with the ground terminal T3 as the reference is described. In this case, in the same way as the first embodiment and as shown in path P5, an electric current in the forward direction flows through the diode 13. With this, the negative surge is discharged, and the protection circuit 10b protects the internal circuit 20.

Next, the flow of the electric current in the third embodiment when a positive surge is applied to the power supply terminal T1 with the ground terminal T3 as the reference is described. In this case, in the same way as the first embodiment and as shown in path P6, an electric current in the reverse direction flows through the diode 13. With this, the positive surge is discharged, and the protection circuit 10b protects the internal circuit 20.

Thus, the third embodiment can discharge surges that have patterns based on the relationships among the breakdown voltages. Furthermore, the element size of the diodes 11 and 12a can be made smaller than the element size of the diode 13. That is, the third embodiment can protect the internal circuit 20 with a reduced circuit area.

### Fourth Embodiment

Next, the semiconductor device according to the fourth embodiment is described with reference to FIG. 4. FIG. 4 is a circuit diagram of the semiconductor device according to the fourth embodiment. The protection circuit 10c according to the fourth embodiment, as shown in FIG. 4, includes four diodes 11 that are series-connected and this is the only difference between the fourth embodiment and the first embodiment.

With the composition mentioned above, even if the breakdown voltage of one diode 11 is low, the breakdown voltage of the whole series can be made higher by series-connecting multiple diodes 11. For this reason, setting the breakdown voltage becomes easier.

### Fifth Embodiment

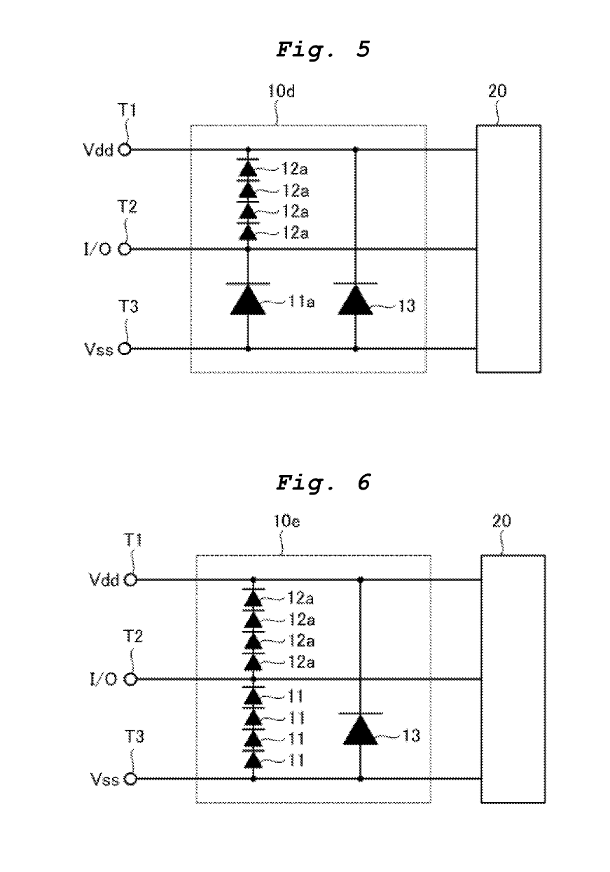

Next, the semiconductor device according to the fifth embodiment is described with reference to FIG. 5. FIG. 5 is a circuit diagram of the semiconductor device according to the fifth embodiment. The protection circuit 10d according to the fifth embodiment, as shown in FIG. 5, includes multiple diodes 12a that are series-connected and this is the only difference between the fifth embodiment and the second embodiment.

With the composition mentioned above, even if the breakdown voltage of one diode 12a is low, the breakdown voltage of the whole series can be made higher by series-connecting multiple diodes 12a.

### Sixth Embodiment

Next, the semiconductor device according to the sixth embodiment is described with reference to FIG. 6. FIG. 6 is a circuit diagram of the semiconductor device according to the sixth embodiment. The protection circuit 10e according to the sixth embodiment, as shown in FIG. 6, includes the multiple diodes 11 and 12a that are series-connected and this is the only difference between the sixth embodiment and the third embodiment.

Because the composition of the sixth embodiment is a combination of the fourth embodiment and the fifth embodiment, a detailed description is omitted.

While certain embodiments have been described, these embodiments have been presented by way of example only and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a first diode having an anode connected to a first power supply terminal to which a first power-source voltage is applied and a cathode connected to an input-output terminal at which input-output signals are input and output;
a second diode having an anode connected to the input-output terminal and a cathode connected to a second power supply terminal to which a second power-source voltage that is higher than the first power-source voltage is applied;
a third diode having an anode connected to the first power supply terminal and a cathode connected to the second power supply terminal; wherein
the breakdown voltage of at least one of the first and second diodes is higher than the breakdown voltage of the third diode; and
the element size of at least one of the first and second diodes of which a breakdown voltage is higher than a breakdown voltage of the third diode is smaller than the element size of the third diode.

2. The semiconductor device of claim 1, wherein the first diode has a higher breakdown voltage than the second and third diodes.

3. The semiconductor device of claim 2, wherein the first diode is composed of multiple diodes each having a lower breakdown voltage than the second and third diodes.

4. The semiconductor device of claim 1, wherein the second diode has a higher breakdown voltage than the first and third diodes.

5. The semiconductor device of claim 4, wherein the second diode is composed of multiple diodes each having a lower breakdown voltage than the first and third diodes.

6. The semiconductor device of claim 1, wherein the first and second diodes each have a higher breakdown voltage than the third diode.

7. The semiconductor device of claim 6, wherein the first and second diodes are each composed of multiple diodes each having a lower breakdown voltage than the third diode.

8. A semiconductor device comprising:
a first diode having an anode connected to a first power supply terminal to which a first power-source voltage is applied and a cathode connected to an input-output terminal to which input-output signals are input and output;
a second diode having an anode connected to the input-output terminal and a cathode connected to a second power supply terminal to which a second power-source voltage that is higher than the first power-source voltage is applied;
a third diode having an anode connected to the first power supply terminal and a cathode connected to the second supply terminal; wherein
the breakdown voltage of at least one of the first and second diodes is higher than the breakdown voltage of the third diode.

9. The semiconductor device of claim 8, wherein
at least one of the first and second diodes having a higher breakdown voltage than the third diode is composed of multiple diodes each having a lower breakdown voltage than the third diode.

10. The semiconductor device of claim 8, wherein the first diode has a higher breakdown voltage than the second and third diodes.

11. The semiconductor device of claim 10, wherein the first diode is composed of multiple diodes each having a lower breakdown voltage than the second and third diodes.

12. The semiconductor device of claim 8, wherein the second diode has a higher breakdown voltage than the first and third diodes.

13. The semiconductor device of claim 12, wherein the second diode is composed of multiple diodes each having a lower breakdown voltage than the first and third diodes.

14. The semiconductor device of claim 8, wherein the first and second diodes each have a higher breakdown voltage than the third diode.

15. The semiconductor device of claim 14, wherein the first and second diodes are each composed of multiple diodes each having a lower breakdown voltage than the third diode.

16. A semiconductor device having a primary circuit and a protection circuit between the primary circuit and terminals of the primary circuit, comprising:
a first diode having an anode connected to a first terminal and a cathode connected to a second terminal;
a second diode having an anode connected to the second terminal and a cathode connected to a third terminal;
a third diode having an anode connected to the first terminal and a cathode connected to the third terminal,
wherein the breakdown voltage of at least one of the first and second diodes is higher than the breakdown voltage of the third diode.

17. The semiconductor device of claim 16, wherein
at least one of the first and second diodes having a higher breakdown voltage than the third diode is composed of multiple diodes each having a lower breakdown voltage than the third diode.

18. The semiconductor device of claim 16, wherein the first diode has a higher breakdown voltage than the second and third diodes.

19. The semiconductor device of claim 16, wherein the second diode has a higher breakdown voltage than the first and third diodes.

20. The semiconductor device of claim 16, wherein the first and second diodes each have a higher breakdown voltage than the third diode.
